(19) United States
(12) Patent Application Publication
(10) Pub. No.: US 2024/0233148 A1
(43) Pub. Date: Jul. 11, 2024

(54) UNSUPERVISED CONTRASTIVE LEARNING FOR DEFORMABLE AND DIFFEOMORPHIC MULTIMODALITY IMAGE REGISTRATION

(71) Applicant: Hyperfine Operations, Inc., Guilford, CT (US)

(72) Inventors: Neel Dey, Guilford, CT (US); Jo Schlemper, Guilford, CT (US); Seyed Sadegh Mohseni Salehi, Guilford, CT (US); Li Yao, Guilford, CT (US); Michal Sofka, Guilford, CT (US)

(73) Assignee: Hyperfine Operations, Inc., Guilford, CT (US)

(21) Appl. No.: 18/611,128

(22) Filed: Mar. 20, 2024

Related U.S. Application Data
(63) Continuation of application No. PCT/US2022/044288, filed on Sep. 21, 2022.
(60) Provisional application No. 63/246,652, filed on Sep. 21, 2021.
(60) Provisional application No. 63/313,234, filed on Feb. 23, 2022.

(51) Int. Cl. G06T 7/33; G06T 3/14

(52) U.S. Cl. CPC G06T 7/337; G06T 3/14; G06T 2207/20081; G06T 2207/20084

(57) ABSTRACT

A computer-implemented method that includes providing as input to the neural network, a first image and a second image. The method further includes obtaining, using the neural network, a transformed image based on the first image that may be aligned with the second image. The method further includes obtaining a plurality of first patches from the transformed image by encoding the transformed image using a first encoder that has a first plurality of encoding layers. The method further includes obtaining a plurality of second patches from the second image by encoding the second image using a second encoder that has a second plurality of encoding layers. The method further includes computing a loss value based on comparison of respective first patches and second patches. The method further includes adjusting one or more parameters of the neural network based on the loss value.

### CROSS-REFERENCES TO RELATED APPLICATION

This application claims priority under 35 U.S.C. § 120 as a continuation of PCT Patent Application No. PCT/US2022/044288 filed Sep. 21, 2022, which claims priority to U.S. Provisional Patent Application No. 63/246,652 titled “Magnetic Resonance Image Registration Techniques,” filed Sep. 21, 2021, and U.S. Provisional Patent Application No. 63/313,234 titled “Machine Learning Techniques for MR Image Registration and Reconstruction,” filed Feb. 23, 2022, the contents of each of which are hereby incorporated by reference herein in their entirety.

### BACKGROUND

Image registration may be a process for transforming, in a pair of images that include a moving image and a fixed image, the moving image to a target image in order to align the moving image to the fixed image. Deformable image registration may be a process of performing a non-linear dense transformation on the moving image to transform the moving image into a target image. The target image may be compared to a fixed image (also known as a source image) to determine differences between the two images. The non-linear dense transformation may be a diffeomorphic transformation if the transformation function is invertible and both the function and its inverse may be differentiable.

Image registration has many biomedical applications. For example, multi-modal (also known as inter-modal) registration of intra-operative to pre-operative imaging may be crucial to various surgical procedures, for example, because image registration may be used to measure the effects of a surgery. In another example, magnetic resonance imaging (MRI) scans of a patient at different times may show details of the growth of a tumor and using images from different modalities may provide additional information that may be used to improve the diagnosis of diseases.

Most commonly used multi-modal MRI similarity functions include information-theoretic approaches working on intensity histograms (e.g., mutual information and its local extensions), approaches focusing on edge alignment (e.g., normalized gradient fields), and those that build local descriptors invariant to imaging domains (e.g., modality invariant neighborhood descriptors). However, due to their hand-crafted nature, these functions typically require significant domain expertise, non-trivial tuning, and may not be consistently generalizable outside of the domain-pair that they were originally proposed for.

The background description provided herein is for the purpose of presenting the context of the disclosure. Content of this background section, as well as aspects of the description that may not otherwise qualify as prior art at the time of filing, are neither expressly nor impliedly admitted as prior art against the present disclosure.

### SUMMARY

Embodiments relate generally to a system and method to train a neural network to perform image registration. According to one aspect, a computer-implemented method includes providing as input to the neural network, a first image and a second image. The method further includes obtaining, using the neural network, a transformed image based on the first image that is aligned with the second image. The method further includes obtaining a plurality of first patches from the transformed image by encoding the transformed image using a first encoder that has a first plurality of encoding layers, wherein one or more patches of the first plurality of patches are obtained from different layers of the first plurality of encoding layers. The method further includes obtaining a plurality of second patches from the second image by encoding the second image using a second encoder that has a second plurality of encoding layers, wherein at least two patches of a second plurality of patches are obtained from different layers of the second plurality of encoding layers. The method further includes computing a loss value based on comparison of respective first patches and second patches. The method further includes adjusting one or more parameters of the neural network based on the loss value.

In some embodiments, before training the neural network to perform image registration the method further includes training the first encoder and the second encoder with joint L1+Local Normalized Cross Correlation (LNCC) loss functions and freezing parameters of the first encoder and the second encoder. In some embodiments, the method further includes training the neural network using a hyperparameter for each loss function by randomly sampling from a uniform distribution during training. In some embodiments, an increase in the hyperparameter results in the neural network outputting a smoother displacement field and a decrease in the hyperparameter results in a deformed first image that is more closely aligned to the second image. In some embodiments, the neural network outputs a displacement field and the method further includes applying, with a spatial transform network, the displacement field to the first image, wherein the spatial transform network outputs the transformed image. In some embodiments, computing a loss value based on comparison of respective first patches and second patches includes: extracting, with the first encoder and the second encoder, multi-scale features for the respective first patches and second patches and applying a loss function based on a comparison of the multi-scale features to determine the loss value. In some embodiments, multilayer perceptrons are applied to the multi-scale features. In some embodiments, the loss function maximizes the multi-scale features and uses a global mutual information loss on image intensity histograms. In some embodiments, training the neural network is an unsupervised process. In some embodiments, different layers of the first plurality of encoding layers correspond to different scales of the transformed image.

According to one aspect, a device includes a processor and a memory coupled to the processor, with instructions stored thereon that, when executed by the processor, cause the processor to perform operations comprising: providing a first image of a first type and a second image of a second type, different from the first type, as input to a trained neural network, obtaining, as output of the trained neural network, a displacement field for the first image, and obtaining a transformed image by applying the displacement field to the first image via a spatial transform network, wherein corresponding features of the transformed image and the second image are aligned.

In some embodiments, the trained neural network employs a hyperparameter. In some embodiments, an increase in the hyperparameter results in the trained neural network outputting a smoother displacement field. In some embodiments, a decrease in the hyperparameter results in a deformed first image that is more closely aligned to the second image. In some embodiments, the first image and the second image are of a human tissue or a human organ. In some embodiments, the transformed image is output for viewing on a display.

A non-transitory computer-readable medium to train a neural network to perform image registration with instructions stored thereon that, when executed by a processor, causes the processor to perform operations, the operations comprising: providing as input to the neural network, a first image and a second image, obtaining, using the neural network, a transformed image based on the first image that is aligned with the second image, obtaining a plurality of first patches from the transformed image by encoding the transformed image using a first encoder that has a first plurality of encoding layers, wherein one or more patches of the first plurality of patches are obtained from different layers of the first plurality of encoding layers, obtaining a plurality of second patches from the second image by encoding the second image using a second encoder that has a second plurality of encoding layers, wherein at least two patches of a second plurality of patches are obtained from different layers of the second plurality of encoding layers, computing a loss value based on comparison of respective first patches and second patches, and adjusting one or more parameters of the neural network based on the loss value.

In some embodiments, before training the neural network to perform image registration, the operations further comprise training the first encoder and the second encoder with joint L1+Local Normalized Cross Correlation (LNCC) loss functions and freezing parameters of the first encoder and the second encoder. In some embodiments, the operations further include training the neural network using a hyperparameter for each loss function by randomly sampling from a uniform distribution during training. In some embodiments, an increase in the hyperparameter results in the neural network outputting a smoother displacement field and a decrease in the hyperparameter results in a deformed first image that is more closely aligned to the second image.

The application advantageously describes systems and methods for an unsupervised process for training a neural network for image registration by training autoencoders and freezing the parameters of the autoencoders, training a neural network for image registration, selecting a hyperparameter that is a compromise between a smoother displacement field and alignment between image pairs, and using a weighted comparison of different loss functions for generating a loss value.

### BRIEF DESCRIPTION OF THE DRAWINGS

FIG. 1 illustrates a block diagram of an example network environment to register images, according to some embodiments described herein.

FIG. 2 illustrates a block diagram of an example computing device to register images, according to some embodiments described herein.

FIG. 3 illustrates an example image registration architecture that includes an example registration component and an example loss computation component, according to some embodiments described herein.

FIG. 4 illustrates example autoencoder architecture and example registration network/STN architectures, according to some embodiments described herein.

FIG. 5 is an example comparison of input pairs to deformed moving images generated with different loss functions, according to some embodiments described herein.

FIG. 6A is an example comparison of input pairs to deformed moving images generated with different loss functions, according to some embodiments described herein.

FIG. 6B is an example comparison of deformed moving images and their corresponding warps when different hyperparameter values were used, according to some embodiments described herein.

FIG. 7 is an example flow diagram to train a neural network to perform image registration, according to some embodiments described herein.

FIG. 8 is another example flow diagram to train a neural network to perform image registration, according to some embodiments described herein.

FIG. 9 is an example flow diagram to perform image registration, according to some embodiments described herein.

FIG. 10 is another example flow diagram to perform image registration, according to some embodiments described herein.

### DETAILED DESCRIPTION

Multimodality image registration occurs when two images include different modalities that may be aligned for comparison. The most widely used application of intermodality registration may be Magnetic Resonance Imaging (MRI), Computed Tomography (CT), Single-Photon Emission Computerized Tomography (SPECT), and Positron Emission Tomography (PET) images of human organs and tissue.

Multimodality image registration includes two main components: a registration component and a loss computation component. The registration component includes a registration network and a spatial transform network. The registration network may be trained based on a particular hyperparameter value that compromises between aligning the images and outputting an image that has smooth features.

The registration component receives a fixed image and a moving image. The fixed image may be, as the name suggests, an image that does not change during the process. The registration network generates a displacement field. The spatial transform network uses the displacement field to warp the moving image to transform the moving image into a deformed moving image.

The loss computation component includes autoencoders and multilayer perceptrons. The autoencoders may be trained to extract multi-scale features from pairs of the fixed image and the deformed moving image. For example, the autoencoders may use patches from the pairs of images for feature extraction and comparison. Once the autoencoder completes the training process, the parameters of the autoencoders may be frozen and the registration network may be subsequently trained. The multilayer perceptrons compare the multi-scale features and determine differences between the multi-scale features, which is known as a loss value.

### Network Environment 100

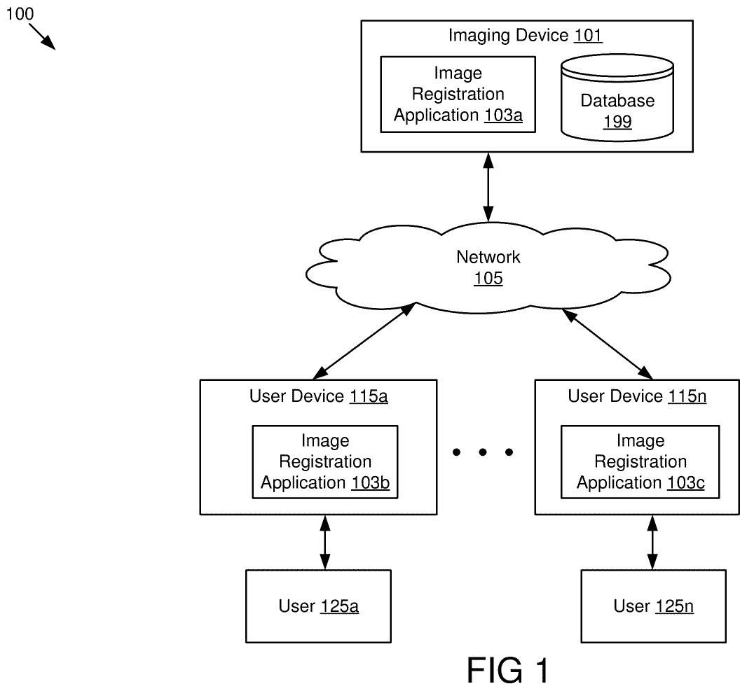

FIG. 1 illustrates a block diagram of an example environment 100 to register images. In some embodiments, the environment 100 includes an imaging device 101, user devices 115a . . . n, and a network 105. Users 125a . . . n may be associated with the respective user devices 115a . . . n. In FIG. 1 and the remaining figures, a letter after a reference number, e.g., “115a,” represents a reference to the element having that particular reference number. A reference number in the text without a following letter, e.g., “115,” represents a general reference to embodiments of the element bearing that reference number. In some embodiments, the environment 100 may include other devices not shown in FIG. 1. For example, the imaging device 101 may be multiple image devices 101.

The imaging device 101 includes a processor, a memory, and imaging hardware. In some embodiments, the imaging device 101 may be an MRI machine, a CT machine, a SPECT machine, a PET machine, etc.

In some embodiments, the imaging device 101 may be a portable low-field MR imaging system. In various aspects of the imaging device 101, the field strength of the MR system may be produced by permanent magnets. In some embodiments, the field strength may be between 1 mT and 500 mT. In some embodiments, the field strength may be between 5 mT and 200 mT. In some embodiments, the average field strength may be between 50 mT and 80 mT.

In various embodiments, the imaging device 101 may be portable. In some embodiments, the imaging device 101 may be less than 60 inches tall, 34 inches wide, and fits through most doorways. In some embodiments, the imaging device 101 may weigh less than 1500 pounds and be movable on castors or wheels. In some embodiments, the imaging device 101 may have a motor to drive one or more wheels to propel the imaging device 101. In some embodiments, the imaging device 101 may have a power supply to provide power to the motor, or the MR system, independent of an external power supply. In some embodiments, the imaging device 101 may draw power from an external power supply, such as a single-phase electrical power supply, like a wall outlet. In some embodiments, the imaging device 101 uses less than 900 W during operation. In some embodiments, the imaging device 101 includes a joystick for guiding movement of the imaging device 101. In some embodiments, the imaging device 101 may include a safety line guard to demarcate a 5 Gauss line about a perimeter of the imaging device.

In some embodiments, the imaging device 101 may include a bi-planar permanent magnet, a gradient component, and at least one radio frequency (RF) component to receive data. In some embodiments, the imaging device 101 may include a base configured to house electronics that operate the imaging device 101. For example, the base may house electronics including, but not limited to, one or more gradient power amplifiers, an on-system computer, a power distribution unit, one or more power supplies, and/or any other power components configured to operate the imaging device 101 using mains electricity. For example, the base may house low-power components, such that the imaging device 101 may be powered from readily available wall outlets. Accordingly, the imaging device may be brought to a patient and plugged into a wall outlet in the vicinity of the patient.

In some embodiments, the imaging device 101 may capture imaging sequences including T1, T2, fluid-attenuated inversion recovery (FLAIR), and diffusion weighted image (DWI) with an accompanying apparent diffusion coefficient (ADC) map.

In some embodiments, the imaging device 101 may be communicatively coupled to the network 105. In some embodiments, the imaging device 101 sends and receives data to and from the user devices 115. In some embodiments, the imaging device 101 is controlled by instructions from a user device 115 via the network.

The imaging device 101 may include an image registration application 103a and a database 199. In some embodiments, the image registration application 103a includes code and routines operable to train a neural network to perform multi-modal image registration. For example, the image registration application 103a may provide as input to the neural network, a first image and a second image, obtain, using the neural network, a first transformed image based on the first image that may be aligned with the second image, compute a first loss value based on a comparison of the first transformed image and the second image, obtain using the neural network, a second transformed image based on the second image that may be aligned with the first image, compute a second loss value based on a comparison of the second transformed image and the first image, and adjust one or more parameters of the neural network based on the first loss value and the second loss value.

In some embodiments, the image registration application 103 may be implemented using hardware including a central processing unit (CPU), a field-programmable gate array (FPGA), an application-specific integrated circuit (ASIC), any other type of processor, or a combination thereof. In some embodiments, the image registration application 103a may be implemented using a combination of hardware and software. In some embodiments, the imaging device 101 may comprise other hardware specifically configured to perform neural network computations/processing and/or other specialized hardware configured to perform one or more methodologies described in detail herein.

The database 199 may be a non-transitory computer readable memory (e.g., random access memory), a cache, a drive (e.g., a hard drive), a flash drive, a database system, or another type of component or device capable of storing data. The database 199 may also include multiple storage components (e.g., multiple drives or multiple databases) that may also span multiple computing devices. The database 199 may store data associated with the image registration application 103a, such as training input images for the autoencoders, training data sets for the registration network, etc.

The user device 115 may be a computing device that includes a memory, a hardware processor, and a display. For example, the user device 115 may include a mobile device, a tablet computer, a mobile telephone, a laptop, a desktop computer, a mobile email device, a reader device, or another electronic device capable of accessing a network 105 and displaying information.

User device 115a includes image registration application 103b and user device 115n includes image registration application 103c. In some embodiments, the image registration application 103b performs the steps of the image registration application 103a described above. In some embodiments, the image registration application 103b receives registered images from the image registration application 103a and displays the registered images for a user 125a, 125n. For example, a user 125 may be a doctor, technician, administration, etc. and may review the results of the image registration application 103a.

In some embodiments, the data from image registration application 103a may be transmitted to the user device 115 via physical memory, via a network 105, or via a combination of physical memory and a network. The physical memory may include a flash drive or other removable media. In some embodiments, the entities of the environment 100 may be communicatively coupled via a network 105. The network 105 may include a public network (e.g., the Internet), a private network (e.g., a local area network (LAN) or wide area network (WAN)), a wired network (e.g., Ethernet network), a wireless network (e.g., an 802.11 network, a Wi-Fi® network, or wireless LAN (WLAN)), a cellular network (e.g., a Long Term Evolution (LTE) network), routers, hubs, switches, server computers, or a combination thereof. Although FIG. 1 illustrates one network 105 coupled to the imaging device 101 and the user devices 115, in practice one or more networks 105 may be coupled to these entities.

### Computing Device Example 200

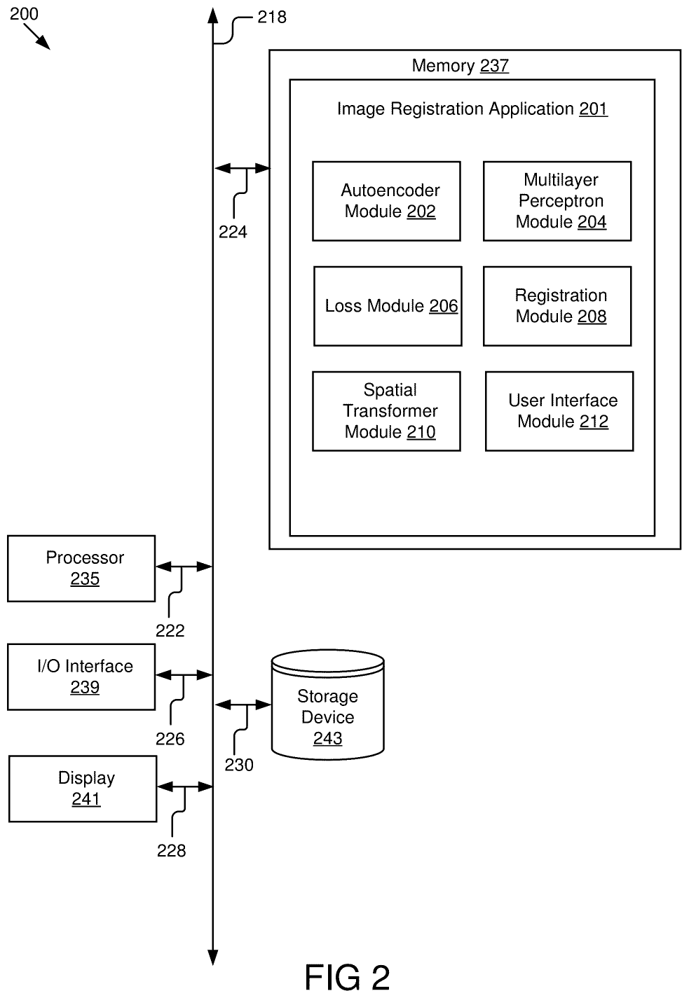

FIG. 2 is a block diagram of an example computing device 200 that may be used to implement one or more features described herein. Computing device 200 may be any suitable computer system, server, or other electronic or hardware device. In some embodiments, computing device 200 may be an imaging device. In some embodiments, the computing device 200 may be a user device.

In some embodiments, computing device 200 includes a processor 235, a memory 237, an Input/Output (I/O) interface 239, a display 241, and a storage device 243. Depending on whether the computing device 200 includes an imaging device or a user device, some components of the computing device 200 may not be present. For example, in instances where the computing device 200 includes an imaging device, the computing device may not include the display 241. In some embodiments, the computing device 200 includes additional components not illustrated in FIG. 2.

The processor 235 may be coupled to a bus 218 via signal line 222, the memory 237 may be coupled to the bus 218 via signal line 224, the I/O interface 239 may be coupled to the bus 218 via signal line 226, the display 241 may be coupled to the bus 218 via signal line 228, and the storage device 243 may be coupled to the bus 218 via signal line 230.

The processor 235 includes an arithmetic logic unit, a microprocessor, a general-purpose controller, or some other processor array to perform computations and provide instructions to a display device. Processor 235 processes data and may include various computing architectures including a complex instruction set computer (CISC) architecture, a reduced instruction set computer (RISC) architecture, or an architecture implementing a combination of instruction sets. Although FIG. 2 illustrates a single processor 235, multiple processors 235 may be included. In different embodiments, processor 235 may be a single-core processor or a multicore processor. Other processors (e.g., graphics processing units), operating systems, sensors, displays, and/or physical configurations may be part of the computing device 200.

The memory 237 stores instructions that may be executed by the processor 235 and/or data. The instructions may include code and/or routines for performing the techniques described herein. The memory 237 may be a dynamic random access memory (DRAM) device, a static RAM, or some other memory device. In some embodiments, the memory 237 also includes a non-volatile memory, such as a static random access memory (SRAM) device or flash memory, or similar permanent storage device and media including a hard disk drive, a compact disc read only memory (CD-ROM) device, a DVD-ROM device, a DVD-RAM device, a DVD-RW device, a flash memory device, or some other mass storage device for storing information on a more permanent basis. The memory 237 includes code and routines operable to execute an image registration application 201 as described in greater detail below.

I/O interface 239 may provide functions to enable interfacing the computing device 200 with other systems and devices. Interfaced devices may be included as part of the computing device 200 or may be separate and communicate with the computing device 200. For example, network communication devices, storage devices (e.g., memory 237 and/or storage device 243), and input/output devices may communicate via I/O interface 239. In another example, the I/O interface 239 may receive data from an imaging device and deliver the data to the image registration application 201 and components of the image registration application 201, such as the autoencoder module 202. In some embodiments, the I/O interface 239 may connect to interface devices such as input devices (keyboard, pointing device, touchscreen, sensors, etc.) and/or output devices (display devices, monitors, etc.).

Some examples of interfaced devices that may connect to I/O interface 239 may include a display 241 that may be used to display content, e.g., images, video, and/or a user interface of an output application as described herein, and to receive touch (or gesture) input from a user. Display 241 may include any suitable display device such as a liquid crystal display (LCD), light emitting diode (LED), or plasma display screen, cathode ray tube (CRT), television, monitor, touchscreen, three-dimensional display screen, or other visual display device.

The storage device 243 stores data related to the image registration application 201. For example, the storage device 243 may store training input images for the autoencoders, training data sets for the registration network, etc.

### Example Image Registration Application 201

FIG. 2 illustrates a computing device 200 that executes an example image registration application 201 that includes an autoencoder module 202, a multilayer perceptron module 204, a loss module 206, a registration module 208, a spatial transformer module 210, and a user interface module 212. Although the modules are illustrated as being part of the same image registration application 201, persons of ordinary skill in the art will recognize that different modules may be implemented by different computing devices 200. For example, the autoencoder module 202, the multilayer perceptron module 204, the registration module 208, and the spatial transformer module 210 may be part of an imaging device and the user interface module 212 may be part of a user device.

The autoencoder module 202 trains modality specific autoencoders to extract multi-scale features from input images. For example, a particular encoder may be trained for a CT scan, an MRI scan, intra-operative scans, pre-operative scans, etc. In some embodiments, the autoencoder module 202 includes a set of instructions executable by the processor 235 to train the autoencoders. In some embodiments, the autoencoder module 202 may be stored in the memory 237 of the computing device 200 and may be accessible and executable by the processor 235.

The autoencoder module 202 trains autoencoders to extract multi-scale features from training input images. In some embodiments, the training may be unsupervised. In some embodiments, the autoencoder module 202 trains two domain-specific autoencoders. For example, the autoencoder module 202 trains a first autoencoder with T1-weighted (T1w) scanned images that may be produced by using shorter Repetition Times (TR) and Time to Echo (TE) times than the TR and TE times used to train T2-weighted (T2w) scanned images. Because the T1w scans and the T2w scans belong to different modalities, the autoencoders may be trained to be part of a multi-modal image registration system.

The training input images may be volumetric images, which are also known as voxels or three-dimensional (3D) images. In some embodiments, the autoencoder module 202 receives T1w and T2w scans of 128×128×128 crops with random flipping and augmentation of brightness, contrast, and/or saturation for training the autoencoders. In some embodiments, the autoencoder module 202 receives T1w and T2w scans and anatomical segmentations and downsamples the images to 2×2×2 mm³ resolution for rapid prototyping.

The autoencoder module 202 trains the domain-specific autoencoders with joint L1+Local Normalized Cross Correlation (LNCC) loss functions. The L1 loss function is also known as least absolute deviations and may be used to minimize the error of the sum of all the absolute differences between a true value and a predicted value. Cross-correlation measures the similarity of two signals (e.g., patches) based on a translation of one signal with another. Normalized cross-correlation restricts the upper bound to 1 as cross-correlation may be unbounded prior to normalization. The Local term in LNCC takes into account a size of a voxel and converges faster and better for training patches than NCC. In some embodiments, the window width of the Local Normalized Cross Correlation (LNCC) loss function may be 7 voxels.

Other loss functions may also be used, such as L1+L2 where the L2 loss function is also known as least square errors. A L2 loss function may be used to minimize the error that is the sum of the squared differences between the true value and the predicted value.

Once the autoencoder module 202 trains the autoencoders, the parameters of the autoencoders may be frozen and used as domain-specific multi-scale feature extractors for training the registration network. In some embodiments, the registration network may be trained using training input images that include preprocessed T1w and T2w MRI scans of newborns imaged at 29-45 weeks gestational age from data provided by the developing Human Connectome Project (dHCP). Using training image data of newborns may be advantageous because image registration of images of newborns may be complicated due to rapid temporal development in morphology and appearance alongside intersubject variability. In some embodiments, the training set images may be further preprocessed to obtain 160×192×160 volumes at 0.6132×0.6257×0.6572 mm³ resolution for training, validation, and testing.

Given a moving image represented as volume I_{T1} and a fixed image represented as volume I_{T2}, during training the registration network predicts a stationary velocity field v, which when numerically integrated with time steps ts, yields an approximately displacement field ϕ. The displacement field may be provided to the STN along with a moving image, where the STN outputs a deformed moving image. The deformed moving image and a fixed image may be received by corresponding autoencoders as discussed in greater detail below.

The autoencoders and the multilayer perceptrons discussed below may be part of a process that maximizes mutual information between a translated image from the input domain X (i.e., the deformed moving image) to an image from the output domain Y (i.e., the fixed image). Put in simpler terms, the autoencoders and the multilayer perceptrons compare whether the translation of a moving image into a deformed moving image makes the deformed moving image sufficiently similar to the fixed image to be able to make useful comparisons of the images.

The autoencoders extract multiscale spatial features A_{T1}^{k}(I_{T1}) and A_{T2}^{k}(ϕ°I_{T2}), where k=1, . . . , L is the layer index and L is the number of layers in the layer index.

In patchwise contrastive loss, a first autoencoder receives a query patch from the fixed image, a second autoencoder receives a positive patch in the deformed moving image at the same location as the query patch and negative patches in the deformed moving image at different locations, and the encoders extract multi-scale features from each of the patches. The autoencoder module 202 transmits the multi-scale features to the multilayer perceptron module 204 in order to compare the differences between (1) the query patch and a positive patch; and (2) the query patch and a negative path. The query patch should be closer in similarity to the positive patch than the negative patches. In some embodiments, the autoencoder module 202 repeats the process of extracting multi-scale features from different patches where the patches may be selected from different locations in an image each time.

Certain image scanning technology, including MRI imaging, capture empty space outside of the body. Random sampling of image pairs introduces false positives and negative pairs (e.g., background voxels sampled as both positive and negative pairs) into the loss computation, which introduces error. In some embodiments, training the registration network included determining whether false positive and negative training pairs interfered with the loss computation. To resolve this issue, in some embodiments, the autoencoders determines mask coordinates that samples image pairs only within the union of the binary foregrounds of I_{T1} and I_{T2} and resizes the mask to the layer-k specific resolution when sampling from A_{T1}^{k}(I_{T1}) and A_{T2}^{k}(ϕ°I_{T2}).

The multilayer perceptron module 204 trains multilayer perceptrons to embed the multi-scale features for comparison. In some embodiments, the multilayer perceptron module 204 includes a set of instructions executable by the processor 235 to compare the multi-scale features. In some embodiments, the multilayer perceptron module 204 may be stored in the memory 237 of the computing device 200 and may be accessible and executable by the processor 235.

The multilayer perceptron module 204 receives multi-scale features extracted from the first autoencoder (e.g., a T1 autoencoder) at a first multilayer perceptron (e.g., a T1 multilayer perceptron) and multi-scale features extracted from the second autoencoder (e.g., a T2 autoencoder) at a second multilayer perceptron (e.g., a T2 multilayer perceptron). In some embodiments, the multilayer perceptron module 204 uses the Simple Framework for Contrastive Learning of visual Representations (SimCLR) algorithms or something similar to maximize the similarity between the extracted features based on a two-layer multilayer perceptrons network.

Continuing with the volume I_{T1} and a fixed image represented as volume I_{T2} discussed with reference to the autoencoders above, because I_{T1} and I_{T2} represent different modalities, a perceptual registration loss may be inappropriate. Instead, the multilayer perceptron module 204 maximizes (i.e., implement a lower bound on) mutual information between corresponding spatial locations in A_{T1}^{k}(I_{T1}) and A_{T2}^{k}(ϕ°I_{T2}) by minimizing a noise contrastive estimation loss.

In some embodiments, the multilayer perceptrons may be used as an embedding function to compare the multi-scale features. The multilayer perceptrons project the channel-wise autoencoder features onto a hyperspherical representation space to obtain features. The channel-wise autoencoder features are of size R^{N}^{^{k}}^{×C}^{^{k}} where N^{k} is the number of spatial indices and C^{k} is the number of channels in layer k. The features obtained by the multilayer perceptrons are F_{T1}^{k}(A_{T1}^{k}(I_{T1})) and F_{T2}^{k}(A_{T2}^{k}(ϕ°I_{T2})) where F_{T1,T2} are three-layer 256-wide trainable rectified linear (ReLU)-multilayer perceptrons. In this space, indices in correspondence fᵢ^{k-} for positive pairs are represented as:

$$\\ \begin{matrix}{f}_{i}^{{}_{} k -} = {F}_{T 1}^{{}_{} k} ( {( {A}_{T 1}^{{}_{} k} ( {I}_{T 1} ) )}_{i} ) and {f}_{i}^{{}_{} k +} = {F}_{T 2}^{{}_{} k} ( {( {A}_{T 2}^{{}_{} k} ( ϕ° {I}_{T 2} ) )}_{j} ) & ( Eq . 1 )\end{matrix}$$

where i=1, . . . , N^{k}, j=1, . . . , N^{k}, and j≠i.

In some embodiments, the multilayer perceptrons sample a single positive pair and ns>>1 negative samples.

The loss module 206 computes a loss function. In some embodiments, the loss module 206 includes a set of instructions executable by the processor 235 to compare the output of the multilayer perceptrons. In some embodiments, the loss module 206 may be stored in the memory 237 of the computing device 200 and may be accessible and executable by the processor 235.

The loss module 206 applies a loss function to compute a loss value. The loss value may be based on applying one or more loss functions. For example, Patch Noise Contrastive Estimation (NCE) may be a patchwise contrastive training scheme that calculates cross-entropy loss with a softmax function to calculate the loss value. In another example, the loss computation may be based on mutual information (MI). In this case, histograms of image intensity of the pairs of image may be calculated and the loss function includes a global mutual information loss on the image intensity histograms. In some embodiments, the loss module 206 compared the accuracy of different loss functions including PatchNCE and MI, PatchNCE alone, MI alone, Local MI, Modality Independent Neighborhood Descriptor (MIND), and Normalized Gradient Fields (NGF) and determined that in some embodiments a weighting of 0.1 PatchNCE+0.9 MI should be used.

In some embodiments, the loss module 206 uses the following contrastive loss function during contrastive training without foreground masks:

$$\\ \begin{matrix}{d}_{T 1 T 2} ( {I}_{T 1} ‖ ϕ° {I}_{T 2} ) = {\sum }_{k = 1}^{L} {\sum }_{i = 1}^{{N}^{{}_{} k}} - log \frac{exp ( {f}_{i}^{{}_{} k} \cdot \frac{{f}_{i}^{{}_{} k -}}{τ} )}{exp ( {f}_{i}^{{}_{} k} \cdot \frac{{f}_{i}^{{}_{} k -}}{τ} ) + {\sum }_{j = 1 , j \neq 1}^{ns} exp ( {f}_{i}^{{}_{} k} \cdot \frac{{f}_{i}^{{}_{} k -}}{τ} )} & ( Eq . 2 )\end{matrix}$$

where τ is a temperature hyperparameter.

The loss module 206 computes a loss value. The loss value may be based on applying the contrastive loss function described in equation 2 or another loss functions. For example, multilayer perceptron module 204 may compare the contrastive loss function in equation 2 to mutual information (MI), Local MI, Modality Independent Neighborhood Descriptor (MIND), and Normalized Gradient Fields (NGF).

In some embodiments, the loss module 206 employs a statistical method called Dice's coefficient to compare the similarity between two samples as a ratio of overlapping portions of a structure in each image to the total volume of the structure in each image.

In some embodiments where the loss module 206 compared the accuracy of different loss functions including PatchNCE and MI, PatchNCE alone, MI alone, Local MI, Modality Independent Neighborhood Descriptor (MIND), and Normalized Gradient Fields (NGF), the loss module 206 determined that 0.1 PatchNCE+0.9 MI achieved a highest overall Dice overlap while maintaining comparable deformation invertibility with negligible folding as a function of an optimal hyperparameter (λ) as compared to the other loss functions.

In some embodiments, where the contrastive loss function in equation 2 was applied, the loss module 206 evaluated the registration performance and robustness as a function of the hyperparameter (λ) via Dice and Dice30 where Dice30 includes the average of the 30% of the lowest dice scores, respectively, calculated between the targeted and moved label maps of the input images. In some embodiments, the deformation smoothness was analyzed based on the standard deviation of the log Jacobian determinant of the displacement field ϕ as a function of the hyperparameter (λ).

The registration module 208 trains a registration network to receive a moving image and a fixed image and output a displacement field. In some embodiments, the registration module 208 includes a set of instructions executable by the processor 235 to train the registration network. In some embodiments, the registration module 208 may be stored in the memory 237 of the computing device 200 and may be accessible and executable by the processor 235.

Deformable image registration aims to find a set of dense correspondences that accurately align two images. In some embodiments, the registration module 208 trains a registration network to register a pair of three-dimensional images where the pair of images may be referred to as a fixed image and a moving image. The registration network may be modeled on a Unet-style VoxelMorph network where a convolutional neural network (CNN) may be trained to align the moving image to match the fixed image. In some embodiments, the autoencoders may be trained before the registration network.

The registration module 208 uses unsupervised learning to train the registration network. The registration module 208 trains the registration network using image pairs from a public database. In some embodiments, the training data sets may be designed for use cases that include high-field to low-field MRI registration and intra-operative multi-modality registration.

Diffeomorphic deformations may be differential and invertible, and preserve topology. In some embodiments, the following equation represents the deformation that maps the coordinates from one image to coordinates in another image:

$$\\ \begin{matrix}ϕ : {ℝ}^{3} \to {ℝ}^{3} & ( Eq . 3 )\end{matrix}$$

The displacement field is defined through the following Ordinary Differential Equation (ODE):

$$\\ \begin{matrix}\frac{ϑ {ϕ}^{{}_{} ( t )} d}{ϑ t} = v ( {ϕ}^{{}_{} ( t )} ) & ( Eq . 4 )\end{matrix}$$

where ϕ⁽⁰⁾=Id is the identity transformation and t is time. The registration module 208 integrates the stationary velocity field v over t=[0, 1] to obtain the final registration field ϕ⁽¹⁾. In some embodiments, the registration module 208 also obtains an inverse deformation field by integrating −v.

A new image pair of a fixed image f and a moving image m are three-dimensional images, such as MRI volumes. The registration module 208 receives the image pair (m, f) as input and outputs a deformation field (ϕ_{z}) (e.g., a diffeomorphic deformation field) using the following equation where z is a velocity field that is sampled and transformed to the deformation field (ϕ_{z}):

$$\\ \begin{matrix}{ϕ}_{z} : {ℝ}^{3} \to {ℝ}^{3} & ( Eq . 5 )\end{matrix}$$

The registration module 208 leverages a neural network with diffeomorphic integration and spatial transform layers that identify increasingly more detailed features and patterns of the images. In some embodiments, the neural network includes filters, downsampling layers with convolutional filters and a stride, and upsampling convolutional layers with filters.

In some embodiments, the registration module 208 trains the registration network using the following loss function:

$$\\ \begin{matrix}( 1 - λ ) {L}_{sim} + λ {L}_{reg} & ( Eq . 6 )\end{matrix}$$

where λ is a hyperparameter randomly and uniformly sampled from [0, 1] during training, L_{reg} represents the various similarity functions to be benchmarked, L_{reg}=∥v₂∥₂² is a regulizer controlling velocity (and indirectly displacement) field smoothness where v is the stationary velocity field, and Lₛᵢₘ is a similarity cost function. In some embodiments, the registration network performs bidirectional registration, which means that a first image may be translated and compared to a second image, and then a second image may be translated and compared to the first image. The cost function for interdomain similarity may be defined by the following equation:

$$\\ \begin{matrix}{L}_{sim} = \frac{1}{2} ( {d}_{T 1 T 2} ( {I}_{T 1} ‖ ϕ° {I}_{T 2} ) + {d}_{T 2 T 1} ( {I}_{T 1} ‖ {ϕ}^{- 1} ° {I}_{T 1} ) & ( Eq . 7 )\end{matrix}$$

where d_{T1T2,T2T1} measures inter-domain similarity.

Registration performance strongly depends on weighting the hyperparameter correctly for a given dataset and Lₛᵢₘ. Selecting a value for the hyperparameter dramatically affects the quality of the displacement field. For example, the value of the hyperparameter may be a compromise between a proper alignment between the images and smooth deformation. Specifically, low hyperparameter values yield strong deformations and high hyperparameter values yield highly regular deformations. For fair comparison, the entire range of the hyperparameter may be evaluated for all benchmarked methods using hypernetworks developed for registration. Specifically, the FiLM based framework may be used with a 4-layer 128-wide ReLU-MLP to generate λ˜U[0,1]-conditioned shared embedding, which may be linearly projected (with a weight decay of 10⁻⁵) to each layer in the registration network to generate λ-conditioned scales and shifts for the network activations. For benchmarking, 17 registration networks were sampled for each method with dense λ sampling between [0,0.2] and sparse sampling between [0.2, 1.0].

In some embodiments, the registration module 208 trains the registration network by testing the value of the hyperparameter from 0 to 1 in increments of 0.1 while comparing the loss function against hand-crafted loss functions and automatically modifying deformation regularity for the loss functions. For example, the loss functions may include MI alone, LMI, NGF, and MIND as baselines while maintaining the same registration network architecture. In some embodiments, the effectiveness of the variables may be tested by determining a Dice overlap between a segmentation of the fixed image and the deformed moving image, which may be an indication of registration correctness, and a percentage of folding voxels, which may be an indication of deformation quality and invertibility. In this example, employing the PatchNCE and MI loss functions with a hyperparameter of 0.6-0.8 results in the best Dice overlap. With these parameters, the registration network has high registration accuracy alongside smooth and diffeomorphic deformations.

Once the registration module 208 trains the registration network and selects a hyperparameter, the registration network may be trained to receive a pair of a fixed image and moving image as input, generate a stationary velocity field, and output a displacement field. The registration module 208 transmits the displacement field to the spatial transformer module 210.

The spatial transformer module 210 outputs a deformed moving image. In some embodiments, the spatial transformer module 210 includes a set of instructions executable by the processor 235 to output the deformed moving image. In some embodiments, the spatial transformer module 210 may be stored in the memory 237 of the computing device 200 and may be accessible and executable by the processor 235.

The spatial transformer module 210 receives the deformation field (ϕ_{z}) from the registration module 208 and the moving image (m) and generates the deformed moving image by warping m via m °ϕ_{z}. The spatial transformer module 210 transmits the deformed moving image to the autoencoder module 202 for extraction of multi-scale features.

The user interface module 212 generates a user interface. In some embodiments, the user interface module 212 includes a set of instructions executable by the processor 235 to generate the user interface. In some embodiments, the user interface module 212 may be stored in the memory 237 of the computing device 200 and may be accessible and executable by the processor 235.

The user interface module 212 generates a user interface for users associated with user devices. The user interface may be used to view the deformed moving image and fixed image. For example, the user may be a medical professional that wants to review the results of an MRI scan. In some embodiments, the user interface module 212 generates a user interface with options for changing system settings.

### Example Image Registration Architecture 300

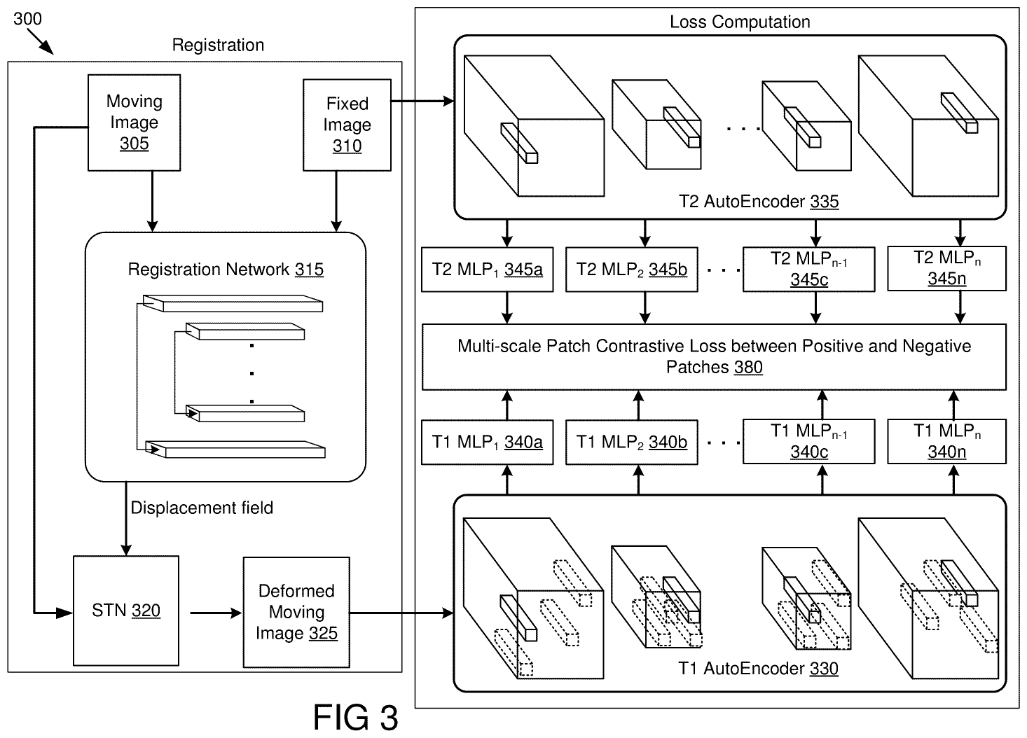

FIG. 3 illustrates an example image registration architecture 300 that includes an example registration component and an example loss computation component. The image registration application 103 determines a transform (e.g., a displacement field) that minimizes a cost function that defines the dissimilarity between the fixed image 310 and the deformed moving image 325. In this example, the image registration architecture 300 includes a registration network 315, a Spatial Transformer Network (STN) 320, a T1 autoencoder 330, a T2 autoencoder 335, a set of T1 Multilayer Perceptrons (MLP) 340, and a set of T2 MLPs 345. The registration component performs registration of the pair of images while the loss computation component calculates a loss value.

The registration network 315 may be modeled on a Unet-style VoxelMorph network. The moving image 305 and the fixed image 310 may be three-dimensional (3D) images that may be provided as input to the registration network 315. The registration network 315 includes a convolutional neural network that concatenates the moving image 305 and the fixed image 310 and outputs a displacement field.

The registration network 315 provides the displacement field as input to the STN 320, which also receives the moving image 305. The STN 320 applies the displacement field to the moving image 305 and outputs a deformed moving image 325.

The T1 autoencoder 330 processes T1-weighted (T1w) scanned images that may be produced by using shorter Repetition Times (TR) and Time to Echo (TE) times. The T2 autoencoder 335 processes scanned images where a T2-weighted (T2w) images may be produced by using longer TR and TE times. Because the T1w scans and the T2w scans belong to different modalities, the image registration architecture 300 may be referred to as multi-modal.

The T1 autoencoder 330, the T1 MLPs 340, the T2 autoencoder 335, and the T2 MLPs 345 maximize mutual information between the fixed image 310 and the deformed moving image 325 in order to determine differences between the fixed image 310 and the deforming moving image 325.

The T1 autoencoder 330 identifies patches of the deformed moving image 325. In some embodiments, the T1 autoencoder 330 extracts a positive patch and multiple negative patches (e.g., in this case three negative patches) for each subset of the T1 autoencoder 330 from different locations in the deformed moving image 325. The positive patch is illustrated by the solid-line hyperrectangle and the negative patches are illustrated by the dashed-line hyperrectangle. Obtaining the negative patches from the deformed moving image 325 instead of relying on other images in a dataset results in the T1 autoencoder 330 optimizing content preservation of the deformed moving image 325. The T2 autoencoder 335 identifies positive patches from the fixed image 310.

The T1 autoencoder 330 and the T2 autoencoder 335 produce image translations for the deformed moving image 325 and the fixed image 310, respectively. The T1 autoencoder 330 and the T2 autoencoder may be convolutional neural networks, which means that each layer of the convolutional neural network for the encoder generates image translations for different sized patches of the input image that get increasingly smaller and each layer of the decoder generates image translations that may be increasingly larger.

The T1 autoencoder 330 transmits the image translations with a corresponding feature stack to a set of T1 MLPs 340a, 340b, 340c, 340n. The T1 MLP₁s produces a stack of features. The T2 autoencoder 335 similarly transmits the image translations with a corresponding feature stack to a set of T2 MLPs 345 a, 345b, 350c, 345n. The T1 MLPs 340 and the T2 MLPs 345 may be projected onto corresponding representation spaces by multilayer perceptrons where the similarity between multiscale features from the fixed image 310 and the deformed moving image 325 may be maximized. Multi-scale patch contrastive loss between positive and negative patches 380 may be calculated, for example, by a loss module. The loss value may be used by the registration network 315 to modify the parameters of the registration network 315. In some embodiments, once the registration network 315 training completes, the loss computation component may no longer be used.

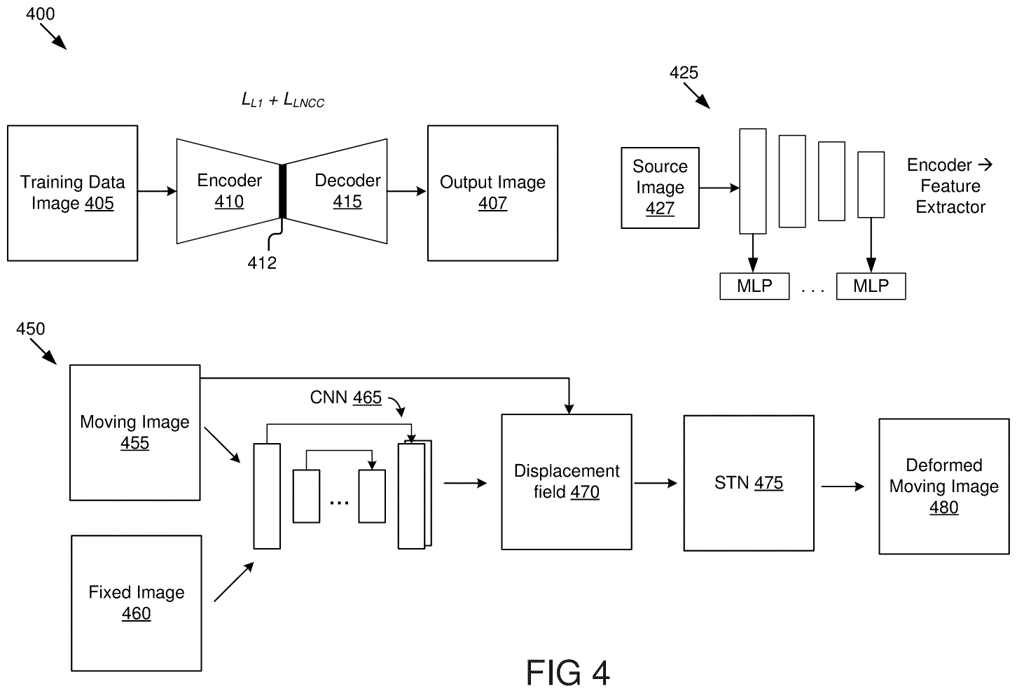

Turning to FIG. 4, an example autoencoder architecture 400, 425 and example registration network/STN architectures 450 are illustrated.

The autoencoder architecture 400 includes an encoder 410 and a decoder 415. The encoder 410 and the decoder 415 may be trained with a joint L1+Local Normalized Cross Correlation (LNCC) loss function. The encoder 410 receives a training data image 405 and generates as output code 412. The decoder 415 receives the code 412 and reconstructs the image (i.e., the output image 407) that may be the same as the training data image 405. By iteratively producing decoded images using different autoencoder parameters to minimize the loss function, the encoder 410 may be trained to generate code 412 that adequately represents the key features of the image. Once the autoencoder module 202 trains the autoencoders, the autoencoders may be frozen and used as domain-specific multi-scale feature extractors for the registration network/STN 450.

The encoder architecture 425 illustrates that the encoder 410 may be a convolutional neural network that acts as a feature extractor. The different layers correspond to different scales of the image. The first layer typically has the same number of nodes as the image size (e.g., for an 8×8 pixel image, the first layer would have 64 input nodes). Later layers may be progressively smaller. The output of different layers represents different features of the source image 427 where each layer of the convolutional neural network has a different understanding of the image. The output may be fed to a respective multilayer perceptron.

In some embodiments, the registration network/STN 450 includes a convolutional neural network 465 and a STN 475. The registration module 208 performs unsupervised training of registration network/STN 450 by providing moving images 455 and fixed images 460 to the convolutional neural network 465. Specifically, the convolutional neural network 465 receives a pair of a moving image 455 and a fixed image 460 to be registered as input and yields a stationary velocity field between the pair of images, which may be efficiently integrated to obtain dense displacement field 470.

Once the pair of images are warped, the encoders 410 may extract multi-scale features from the moving image 455 and the fixed image 460 with the frozen pretrained encoders 410 and then MLPs (not illustrated) project the extracted features onto a representation space where the similarity between multiscale features from the moving image 455 and the fixed image 460 may be maximized. In some embodiments, the MLPs use a global mutual information loss on image intensity histograms for a final registration loss of (0.1 PatchNCE+0.9 MI). In some embodiments, the MLPs employ a diffusion regulizer to ensure smooth deformations.

Once the registration network/STN 450 completes the training process, a moving image 455 and a fixed image 460 may be received as input to the CNN 465. In some embodiments, the CNN 465 outputs approximate posterior probability parameters representing a velocity field mean and variance. A velocity field may be sampled and transformed to a displacement field 470 using squaring and scaling integration layers. The STN 475 receives the moving image 455 and warps the moving image 455 using the displacement field 470 to obtain a deformed moving image 480.

### Example Comparisons of Loss Functions

In one example, the multilayer perceptron module 204 analyzes different loss functions using results from the same registration network where the channel width (ch)=64 and the time step (ts)=5. The loss functions include MI with 48 bins and patch size=9, MIND where distance=2 and patch size=3, NGF, the contrastive loss function in equation 2, and the contrastive loss function in equation 2 including masking. In some embodiments, the multilayer perceptron module 204 compares the results against the general-purpose SynthMorph (SM)-shapes and brain models by using their publicly released models and affine-aligning the images to their atlas.

In some embodiments, because SM uses channel width (ch)=256, the proposed models may be retrained at that width and hyperparameter conditioning and evaluation may not be performed for SM. In this example, the image pairs were from the developing Human Connectome Project (dHCP), which requires large non-smooth deformations. The multilayer perceptron module 204 studied whether a higher number of integration steps improved deformation characteristics for the (ch)=256 model where (ts)={10, 16, 32} with 32 as the default.

The multilayer perceptron module 204 analyzed whether improved results occurred from a global loss (+MI), incorporating more negative samples from an external randomly-selected subject (+ExtNegs), or both (+MI+ExtNegs). Lastly, the multilayer perceptron module 204 analyzed whether contrastive pre-training of the autoencoders by using ground truth multi-modality image pairs alongside the reconstruction losses (+SupPretrain) lead to improved results with the following loss:

$$\\ \begin{matrix}{ℒ}_{{A}_{T 1} , {A}_{T 2} , {F}_{T 1} , {F}_{T 2 a}} = {λ}_{sp} {d}_{T 1 T 2} ( {I}_{T 1 ,} {I}_{T 2} ) + {\sum }_{i = 1}^{2} ( {‖ {I}_{Ti} - {I}_{Ti}^{{}^{{}_{\hat{}}}} ‖}_{1} + NCC ( {I}_{Ti} , {I}_{Ti} ) ) & ( Eq . 8 )\end{matrix}$$

where I_{T1,T2} are from the same subject, λₛₚ=0.1, and I_{Ti, \hat{T}2} are the reconstructions.

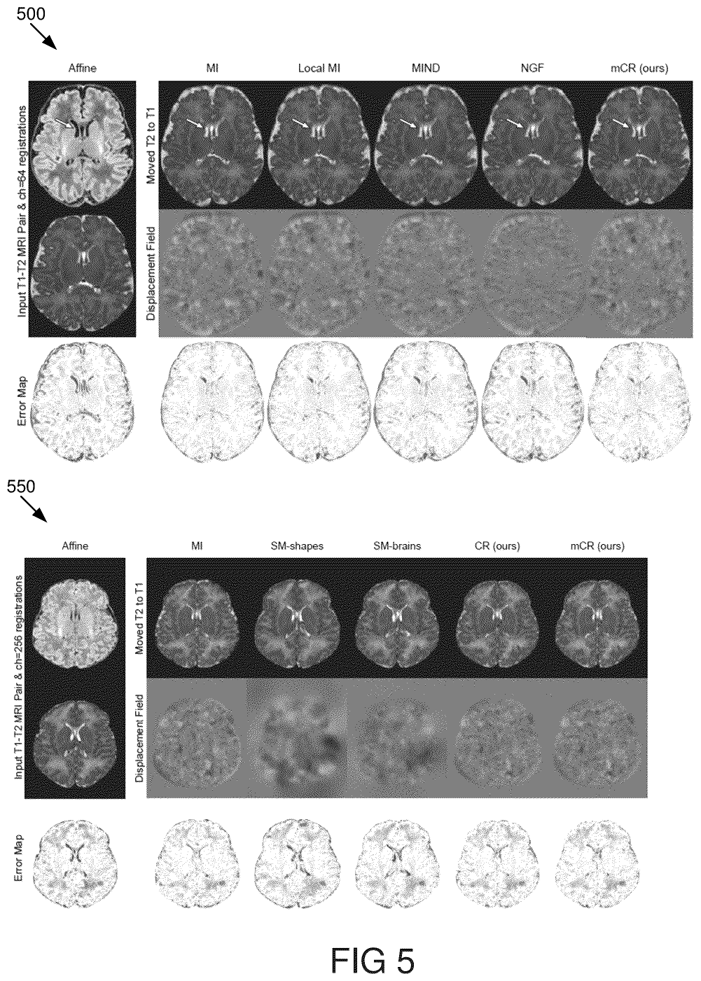

FIG. 5 is an example comparison of the input pairs to deformed moving images generated with different loss functions described above. In the first example 500, the channel width (ch) for the autoencoders is 64. The input pair were generated from T1-weighted and T2-weighted scanned images. The deformed moving images were generated using the following loss functions: MI, Local MI, MIND, NGF, and the contrastive learning loss function described above with masking. The contrastive learning loss function described above with masking was determined to be the best loss function.

The second example illustrates the comparisons using SM as described above where the channel width for the autoencoders is 256. The input pair were generated from T1-weighted and T2-weighted scanned images. The deformed moving images were generated using the following loss functions: MI, Local MI, MIND, NGF, contrastive learning loss function described above (CR) without masking, and the contrastive learning loss function described above with masking (mCR).

Table 1 below illustrates the results of the registration accuracy through Dice values, the robustness through Dice 30 values, and characteristics through the % folds and SD log(|J_{φ}|) as a function of different hyperparameter values (λ) where the hyperparameter may be kept at values that maintain the percentage of folding voxels at less than 0.5% of all voxels.

TABLE 1
Trading off performance for invertibility

| | | | | | | | SDlog |
|---|---|---|---|---|---|---|---|
| Set | Width | Method | Opt. λ | Dice (↑) | Dice30 (↑) | % Folds (↓) | \|J_{φ}\| (↓) |
| A | 64 | NGF [10] | 0.0 | 0.696 ± 0.023 | 0.686 | 0.141 ± 0.043 | 0.072 |
| | 64 | MI [38] | 0.175 | 0.748 ± 0.021 | 0.739 | 0.461 ± 0.100 | 0.089 |
| | 64 | LocalMI [7] | 0.125 | 0.745 ± 0.023 | 0.737 | 0.402 ± 0.076 | 0.083 |
| | 64 | MIND [13] | 0.3 | 0.726 ± 0.023 | 0.716 | 0.258 ± 0.051 | 0.079 |
| | 64 | CR (ours) | 0.05 | 0.775 ± 0.020 | 0.767 | 0.468 ± 0.074 | 0.084 |
| | 64 | mCR (ours) | 0.125 | 0.777 ± 0.020 | 0.769 | 0.419 ± 0.066 | 0.082 |
| B | 256 | SM-brains [15] | — | 0.755 ± 0.020 | 0.749 | 0.023 ± 0.008 | 0.048 |
| | 256 | SM-shapes [15] | — | 0.721 ± 0.021 | 0.715 | 0.017 ± 0.011 | 0.056 |
| | 256 | MI [38] | 0.2 | 0.759 ± 0.021 | 0.750 | 0.487 ± 0.099 | 0.090 |
| | 256 | CR (ours) | 0.075 | 0.772 ± 0.021 | 0.764 | 0.336 ± 0.059 | 0.079 |
| | 256 | mCR (ours) | 0.15 | 0.779 ± 0.021 | 0.772 | 0.433 ± 0.064 | 0.082 |
| C | 64 | CR + MI | 0.3 | 0.750 ± 0.021 | 0.741 | 0.253 ± 0.002 | 0.080 |
| | 64 | CR + ExtNegs | 0.05 | 0.764 ± 0.020 | 0.750 | 0.495 ± 0.077 | 0.086 |
| | 64 | CR + MI + ExtNegs | 0.3 | 0.750 ± 0.021 | 0.741 | 0.253 ± 0.062 | 0.080 |
| | 64 | CR + SupPretrain | 0.025 | 0.776 ± 0.020 | 0.769 | 0.475 ± 0.081 | 0.084 |
| | 64 | mCR + SupPretrain | 0.075 | 0.778 ± 0.020 | 0.770 | 0.415 ± 0.074 | 0.082 |
| D | 256 | CR (10 int. steps) | 0.075 | 0.771 ± 0.021 | 0.762 | 0.350 ± 0.060 | 0.080 |
| | 256 | CR (16 int. steps) | 0.075 | 0.771 ± 0.021 | 0.763 | 0.361 ± 0.061 | 0.080 |
| | 256 | CR (32 int. steps) | 0.075 | 0.772 ± 0.021 | 0.764 | 0.336 ± 0.059 | 0.079 |

Based on FIG. 5 and Table 1, the following determinations may be made. At larger model sizes, mCR and CR still obtain higher registration accuracy and robustness, albeit at the cost of more irregular deformations in comparison to SM. Further adding external losses, negative samples, or both to CR harms performance, and supervised pretraining only marginally improves results over training from scratch. Increasing integration steps yields minimal improvements in dHCP registration performance.

The contrastive learning loss function described above with masking (mCR) was determined to be the best loss function for the following reasons.

MCR achieves higher accuracy and converges faster than baseline losses. FIG. 3 (row 1) indicates that the proposed models achieve better Dice with comparable (mCR) or better (CR) folding and smoothness characteristics in comparison to baseline losses as a function of the 17 values of the hyperparameter that were tested. Further, Table 1 reveals that reducing anatomical overlap to also achieve negligible folding (as defined by folds in 0.5% of all voxels) still results in CR and mCR achieving the optimal tradeoff.

MCR achieves more accurate registration than label-trained methods alongside rougher deformations. While the public SM-brains model does not achieve the same Dice score as mCR, it achieves the third-highest performance behind mCR with substantially smoother deformations. This effect stems from the intensity-invariant label-based training of SM-brains only looking at the semantics of the image, whereas the approach described in the application and other baselines may be appearance based.

Masking consistently improves results. Excluding false positive and false negative pairs from the training patches yields improved registration performance across all values of the hyperparameter with acceptable increases in deformation irregularities vs. the hyperparameter. Contrastive training without foreground masks (CR) still outperforms other baseline losses and does so with smoother warps.

Using external losses or negatives with mCR do not improve results. Combining a global loss (MI) with CR does not improve results, which may be due to the inputs already being globally affine-aligned.

Lastly, self-supervision yields nearly the same performance as supervised pretraining. Comparing rows A5-6 and C4-5 of Table 1 reveals that utilizing supervised pairs of aligned images for pretraining A_{T1,T2} and F_{T1,T2} yields very similar results, indicating that supervision may not be required for optimal registration in this context.

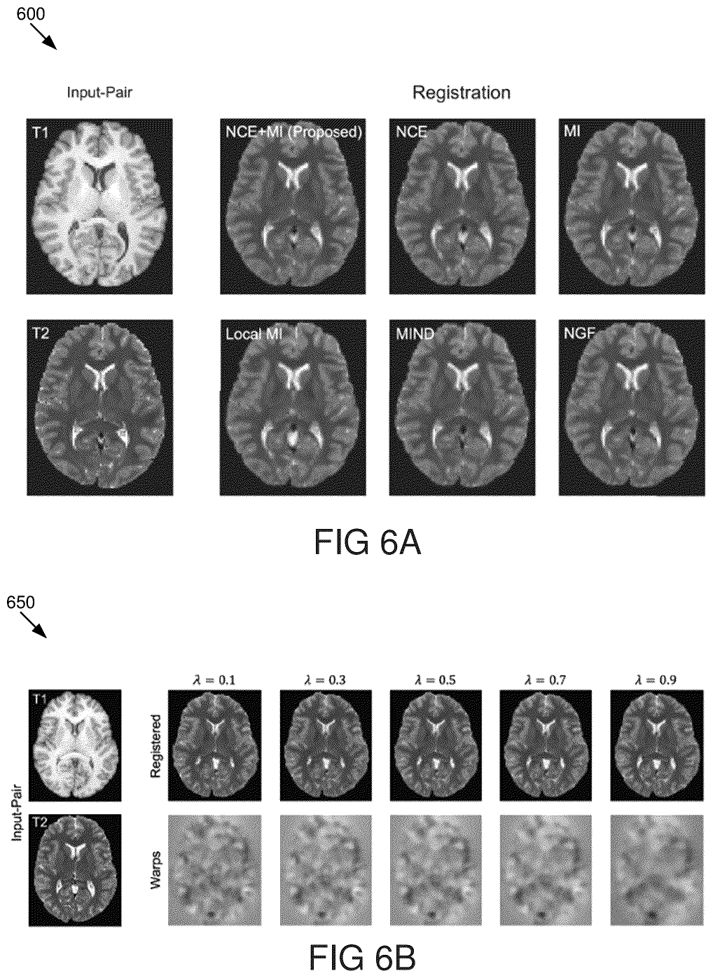

FIG. 6A is an example comparison 600 of input pairs to deformed moving images generated with different loss functions. The input pair were generated from T1-weighted and T2-weighted scanned images. The deformed moving images were generated using the following loss functions: PatchNCE+MI, NCE, MI, Local MI, MIND, and NGF and PatchNCE+MI was determined to be the best loss function.

FIG. 6B is an example comparison 650 of deformed moving images and their corresponding warps when different hyperparameter values were used from 0.1 to 0.9. The best value for the hyperparameter (λ) was determined to be between 0.6-0.8 when the PatchNCE loss function may be used.

### Example Methods

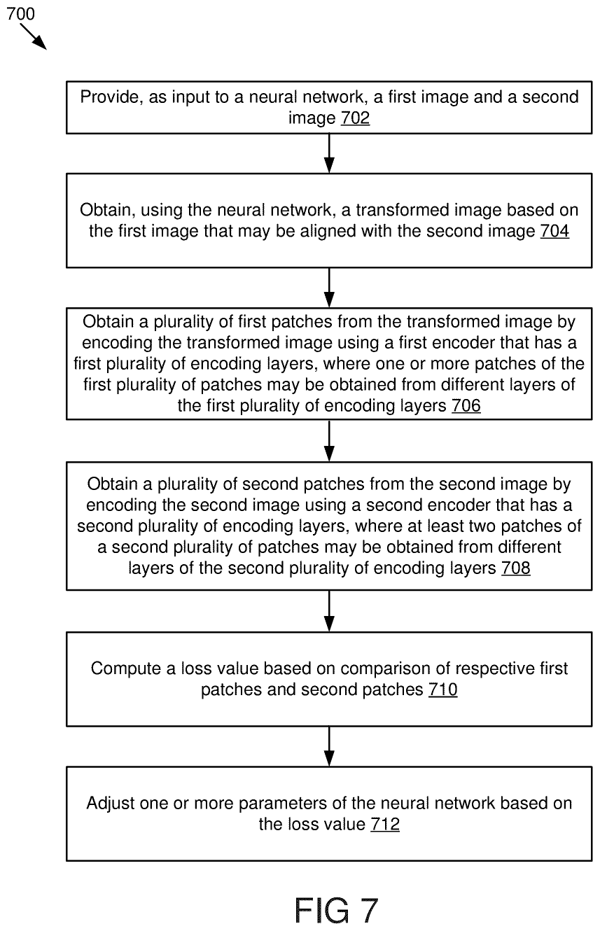

FIG. 7 is an example flow diagram 700 to train a neural network to perform image registration. In some embodiments, the method 700 may be performed by an image registration application stored on an imaging device. In some embodiments, the method 700 may be performed by an image registration application stored on a user device. In some embodiments, the method 700 may be performed by an image registration application stored in part on an imaging device and in part on a user device.

In some embodiments, the method 700 begins at block 702. At block 702, a first image and a second image may be provided as input to a neural network. In some embodiments, the first image may be a moving image and the second image may be a fixed image. In some embodiments, the moving image may be a t1w scanned image and the fixed image may be a t2w scanned image. In some embodiments, before block 702, a first autoencoder and a second autoencoder may be trained with loss functions and the parameters of the first autoencoder and the second autoencoder may be frozen. Block 702 may be followed by block 704.

At block 704, a transformed image may be obtained using the neural network based on the first image that may be aligned with the second image. For example, the first image may be provided to the neural network, which outputs a displacement field. An STN applies the displacement field to the first image and outputs the transformed image. Block 704 may be followed by block 706.

At block 706, a plurality of first patches may be obtained from the transformed image by encoding the transformed image using a first encoder that has a first plurality of encoding layers, where one or more patches of the first plurality of patches may be obtained from different layers of the first plurality of encoding layers. In some embodiments, the first plurality of patches includes positive patches that correspond to a second plurality of patches and negative patches that do not correspond to the second plurality of patches. Block 706 may be followed by block 708.

At block 708, a plurality of second patches may be obtained from the second image by encoding the second image using a second encoder that has a second plurality of encoding layers, where at least two patches of a second plurality of patches may be obtained from different layers of the second plurality of encoding layers. In some embodiments, the second plurality of patches includes query patches. Block 708 may be followed by block 710.

At block 710 a loss value may be computed based on comparison of respective first patches and second patches. Block 710 may be followed by block 712.

At block 712, one or more parameters of the neural network may be adjusted based on the loss value.

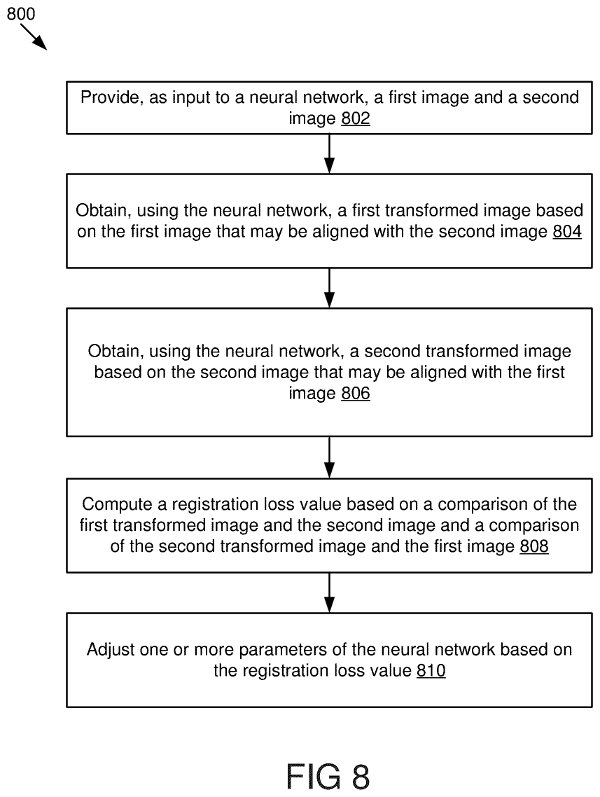

FIG. 8 is an example flow diagram 800 to train a neural network to perform image registration. In some embodiments, the method 800 may be performed by an image registration application stored on an imaging device. In some embodiments, the method 800 may be performed by an image registration application stored on a user device. In some embodiments, the method 800 may be performed by an image registration application stored in part on an imaging device and in part on a user device.

In some embodiments, the method 800 begins at block 802. At block 802, a first image and a second image may be provided as input to a neural network. In some embodiments, the first image may be a moving image and the second image may be a fixed image. In some embodiments, the moving image may be a t1w scanned image and the fixed image may be a t2w scanned image. Block 802 may be followed by block 804.

At block 804, a first transformed image based on the first image that may be aligned with the second image may be obtained using the neural network. Block 804 may be followed by block 806.

At block 806, a second transformed image based on the second image that may be aligned with the first image may be obtained using the neural network. Block 806 may be followed by block 808.

At block 808, a loss value may be computed based on a comparison of the first transformed image and the second image and a comparison of the second transformed image and the first image. Block 808 may be followed by block 810.

At block 810, one or more parameters of the neural network may be adjusted based on the loss value.

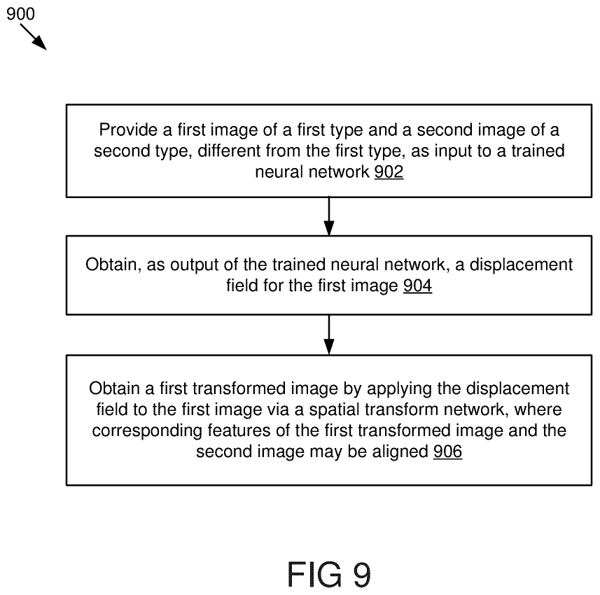

FIG. 9 is an example flow diagram 900 to perform image registration. In some embodiments, the method 900 may be performed by an image registration application stored on an imaging device. In some embodiments, the method 900 may be performed by an image registration application stored on a user device. In some embodiments, the method 900 may be performed by an image registration application stored in part on an imaging device and in part on a user device.

In some embodiments, the method 900 begins at block 902. At block 902, a first image of a first type and a second type, different from the first type, may be provided as input to a trained neural network. In some embodiments, the first image may be a moving image and the second image may be a fixed image. In some embodiments, the moving image may be a t1w scanned image and the fixed image may be a t2w scanned image. Block 902 may be followed by block 904.

At block 904, a displacement field for the first image may be obtained as output of the trained neural network. Block 904 may be followed by block 906.

At block 906, a first transformed image may be obtained by applying the displacement field to the first image via an STN, where corresponding features of the first transformed image and the second image may be aligned.

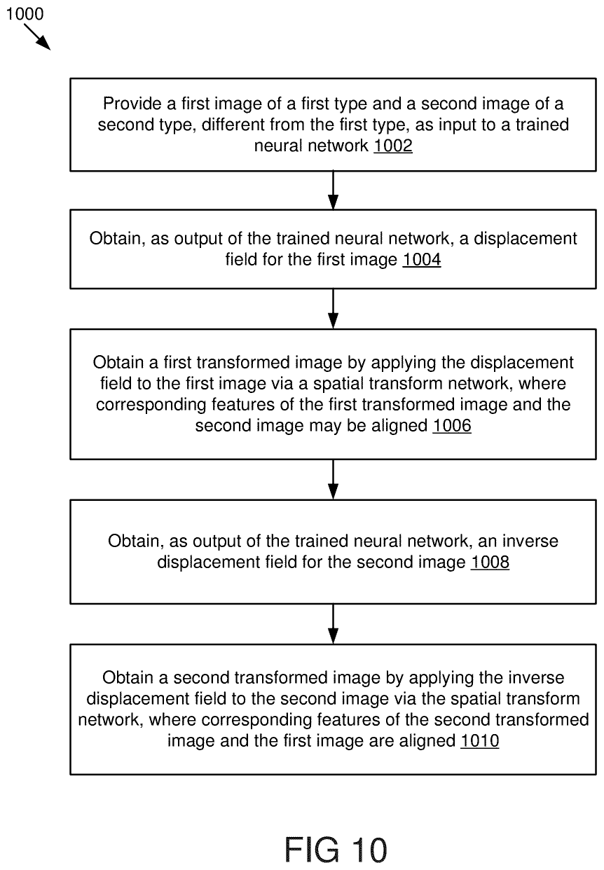

FIG. 10 is another example flow diagram 1000 to perform image registration. In some embodiments, the method 900 may be performed by an image registration application stored on an imaging device. In some embodiments, the method 900 may be performed by an image registration application stored on a user device. In some embodiments, the method 900 may be performed by an image registration application stored in part on an imaging device and in part on a user device.

In some embodiments, the method 1000 begins at block 1002. At block 1002, a first image of a first type and a second type, different from the first type, may be provided as input to a trained neural network. In some embodiments, the first image may be a moving image and the second image may be a fixed image. In some embodiments, the moving image may be a t1w scanned image and the fixed image may be a t2w scanned image. Block 1002 may be followed by block 1004.

At block 1004, a displacement field for the first image may be obtained as output of the trained neural network. Block 1004 may be followed by block 1006.

At block 1006, a first transformed image may be obtained by applying the displacement field to the first image via an STN, where corresponding features of the first transformed image and the second image may be aligned. Block 1006 may be followed by block 1008.

At block 1008, an inverse displacement field for the second image may be obtained as output of the trained neural network. Block 1008 may be followed by block 1010.

At block 1010, a second transformed image may be obtained by applying the inverse displacement field to the second image via the spatial transformed network, where corresponding features of the second transformed image and the first image may be aligned.

The methods, blocks, and/or operations described herein may be performed in a different order than shown or described, and/or performed simultaneously (partially or completely) with other blocks or operations, where appropriate. Some blocks or operations may be performed for one portion of data and later performed again, e.g., for another portion of data. Not all of the described blocks and operations need be performed in various implementations. In some implementations, blocks and operations may be performed multiple times, in a different order, and/or at different times in the methods.

In the above description, for purposes of explanation, numerous specific details may be set forth in order to provide a thorough understanding of the specification. It will be apparent, however, to one skilled in the art that the disclosure may be practiced without these specific details. In some instances, structures and devices may be shown in block diagram form in order to avoid obscuring the description. For example, the embodiments may be described above primarily with reference to user interfaces and particular hardware. However, the embodiments may apply to any type of computing device that may receive data and commands, and any peripheral devices providing services.

Reference in the specification to “some embodiments” or “some instances” means that a particular feature, structure, or characteristic described in connection with the embodiments or instances may be included in at least one implementation of the description. The appearances of the phrase “in some embodiments” in various places in the specification may not necessarily all refer to the same embodiments.

Some portions of the detailed descriptions above may be presented in terms of algorithms and symbolic representations of operations on data bits within a computer memory. These algorithmic descriptions and representations may be the means used by those skilled in the data processing arts to most effectively convey the substance of their work to others skilled in the art. An algorithm may be conceived to be a self-consistent sequence of steps leading to a desired result. The steps may require physical manipulations of physical quantities. Usually, though not necessarily, these quantities take the form of electrical or magnetic data capable of being stored, transferred, combined, compared, and otherwise manipulated. It has proven convenient at times, principally for reasons of common usage, to refer to these data as bits, values, elements, symbols, characters, terms, numbers, or the like.

It should be borne in mind, however, that all of these and similar terms may be associated with the appropriate physical quantities and may be merely convenient labels applied to these quantities. Unless specifically stated otherwise as apparent from the following discussion, it is appreciated that throughout the description, discussions utilizing terms including “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission, or display devices.

The embodiments of the specification may also relate to a processor for performing one or more steps of the methods described above. The processor may be a special-purpose processor selectively activated or reconfigured by a computer program stored in the computer. Such a computer program may be stored in a non-transitory computer-readable storage medium, including, but not limited to, any type of disk including optical disks, ROMs, CD-ROMs, magnetic disks, RAMS, EPROMs, EEPROMs, magnetic or optical cards, flash memories including USB keys with non-volatile memory, or any type of media suitable for storing electronic instructions, each coupled to a computer system bus.

The specification may take the form of some entirely hardware embodiments, some entirely software embodiments or some embodiments containing both hardware and software elements. In some embodiments, the specification may be implemented in software, which includes, but is not limited to, firmware, resident software, microcode, etc.

Furthermore, the description may take the form of a computer program product accessible from a computer-usable or computer-readable medium providing program code for use by or in connection with a computer or any instruction execution system. For the purposes of this description, a computer-usable or computer-readable medium may be any apparatus that may contain, store, communicate, propagate, or transport the program for use by or in connection with the instruction execution system, apparatus, or device.

A data processing system suitable for storing or executing program code will include at least one processor coupled directly or indirectly to memory elements through a system bus. The memory elements may include local memory employed during actual execution of the program code, bulk storage, and cache memories which provide temporary storage of at least some program code in order to reduce the number of times code must be retrieved from bulk storage during execution.

What is claimed is:

1. A computer-implemented method to train a neural network to perform image registration, the method comprising:
providing as input to the neural network, a first image and a second image;
obtaining, using the neural network, a transformed image based on the first image that is aligned with the second image;
obtaining a plurality of first patches from the transformed image by encoding the transformed image using a first encoder that has a first plurality of encoding layers, wherein one or more patches of the first plurality of patches are obtained from different layers of the first plurality of encoding layers;
obtaining a plurality of second patches from the second image by encoding the second image using a second encoder that has a second plurality of encoding layers, wherein at least two patches of a second plurality of patches are obtained from different layers of the second plurality of encoding layers;
computing a loss value based on comparison of respective first patches and second patches; and
adjusting one or more parameters of the neural network based on the loss value.

2. The computer-implemented method of claim 1, wherein before training the neural network to perform image registration, further comprising:
training the first encoder and the second encoder with joint L1+Local Normalized Cross Correlation (LNCC) loss functions; and
freezing parameters of the first encoder and the second encoder.

3. The computer-implemented method of claim 1, further comprising:
training the neural network using a hyperparameter for each loss function by randomly sampling from a uniform distribution during training.

4. The computer-implemented method of claim 3, wherein an increase in the hyperparameter results in the neural network outputting a smoother displacement field and a decrease in the hyperparameter results in a deformed first image that is more closely aligned to the second image.

5. The computer-implemented method of claim 1, wherein the neural network outputs a displacement field and further comprising:
applying, with a spatial transform network, the displacement field to the first image, wherein the spatial transform network outputs the transformed image.

6. The computer-implemented method of claim 1, wherein computing the loss value based on comparison of respective first patches and second patches includes:
extracting, with the first encoder and the second encoder, multi-scale features for the respective first patches and second patches; and
applying a loss function based on a comparison of the multi-scale features to determine the loss value.

7. The computer-implemented method of claim 6, wherein multilayer perceptrons are applied to the multi-scale features.

8. The computer-implemented method of claim 6, wherein the loss function maximizes the multi-scale features and uses a global mutual information loss on image intensity histograms.

9. The computer-implemented method of claim 1, wherein training the neural network is an unsupervised process.

10. The computer-implemented method of claim 1, wherein different layers of the first plurality of encoding layers correspond to different scales of the transformed image.

11. A device to perform image registration, the device comprising:
one or more processors; and
a memory coupled to the one or more processors, with instructions stored thereon that, when executed by the processor, cause the one or more processors to perform operations comprising:
providing a first image of a first type and a second image of a second type, different from the first type, as input to a trained neural network;
obtaining, as output of the trained neural network, a displacement field for the first image; and
obtaining a transformed image by applying the displacement field to the first image via a spatial transform network, wherein corresponding features of the transformed image and the second image are aligned.

12. The device of claim 11, wherein the trained neural network employs a hyperparameter.

13. The device of claim 12, wherein an increase in the hyperparameter results in the trained neural network outputting a smoother displacement field.

14. The device of claim 12, wherein a decrease in the hyperparameter results in a deformed first image that is more closely aligned to the second image.

15. The device of claim 11, wherein the first image and the second image are of a human tissue or a human organ.

16. The device of claim 11, wherein the transformed image is output for viewing on a display.

17. A non-transitory computer-readable medium to train a neural network to perform image registration with instructions stored thereon that, when executed by a processor, cause the processor to perform operations, the operations comprising:
providing as input to the neural network, a first image and a second image;
obtaining, using the neural network, a transformed image based on the first image that is aligned with the second image;
obtaining a plurality of first patches from the transformed image by encoding the transformed image using a first encoder that has a first plurality of encoding layers, wherein one or more patches of the first plurality of patches are obtained from different layers of the first plurality of encoding layers;
obtaining a plurality of second patches from the second image by encoding the second image using a second encoder that has a second plurality of encoding layers, wherein at least two patches of a second plurality of patches are obtained from different layers of the second plurality of encoding layers;
computing a loss value based on comparison of respective first patches and second patches; and
adjusting one or more parameters of the neural network based on the loss value.

18. The computer-readable medium of claim 17, wherein before training the neural network to perform image registration, the operations further comprise:
training the first encoder and the second encoder with joint L1+Local Normalized Cross Correlation (LNCC) loss functions; and
freezing parameters of the first encoder and the second encoder.

19. The computer-readable medium of claim 17, wherein the operations further comprise:
training the neural network using a hyperparameter for each loss function by randomly sampling from a uniform distribution during training.

20. The computer-readable medium of claim 19, wherein an increase in the hyperparameter results in the neural network outputting a smoother displacement field and a decrease in the hyperparameter results in a deformed first image that is more closely aligned to the second image.
